(19) United States
(12) Patent Application Publication
(10) Pub. No.: US 2007/0096239 A1
(43) Pub. Date: May 3, 2007

(54) Semiconductor devices and methods of manufacture

(75) Inventors: Xian-An Cao, New Paltz, NY (US); Stephen Daley Arthur, Glenville, NY (US)

Correspondence Address: General Electric Company;GEGR Patent Docket Rm., Bldg. K-1 Rm. 4A59, One Research Circle, Niskayuna, NY, 12309, US

(73) Assignee: General Electric Company

(21) Appl. No.: 11/263,163

(22) Filed: Oct. 31, 2005

(51) Int. Cl. H01L 31/00

(52) U.S. Cl. 257/458; 257/E31.061

(57) ABSTRACT

A semiconductor device includes a substrate comprising a material selected from the group consisting of AlN, SiC, GaN, sapphire and combinations thereof. An n⁺ type epitaxial layer is disposed above substrate and comprises GaN or AlGaN. An n− type epitaxial layer is disposed above substrate and comprises GaN or AlGaN. A p⁺-n junction grid comprising p⁺ GaN or p⁺ AlGaN is formed on selective areas of the n− type epitaxial layer. A metal layer is disposed over the p⁺-n junction grid and forms a Schottky contact. Another metal layer is deposited on one of the substrate and the n+ type epitaxial layer and forms a cathode electrode. A method of fabricating a semiconductor device is provided and includes forming a p⁺-n junction grid on a drift layer comprising GaN or AlGaN.

### BACKGROUND

The invention relates generally to semiconductor devices and more particularly to gallium nitride (GaN) and aluminum gallium nitride (AlGaN) based semiconductor devices.

Silicon power devices are reaching their fundamental limit of performance. Electronic devices based on Group-III nitrides, which include InN, GaN and AIN and their alloys, offer superior high voltage, high power, high temperature, and high frequency operation as compared to analogous devices based on silicon. GaN has a wide band gap of 3.4 eV, high critical electric field and high electron mobility, and thus is promising as an alternative to SiC for high voltage power conversion applications. The band gap of AlGaN alloys can be tuned in the range of 3.4-6.2 eV by varying the percentage of aluminum in the alloy. AlGaN-based power devices are therefore able to tolerate even higher temperatures and maintain large breakdown voltages in smaller geometries, enabling higher switching performance. Furthermore, GaN/AlGaN heterostructures provide a great deal of flexibility for novel device design.

One defining feature of the nitride material system is the lack of high-quality bulk GaN or AIN substrates. To date, most GaN-based devices are grown heteroepitaxially on foreign substrates, such as sapphire and SIC. The mismatch in lattice constant and thermal expansion coefficient between the epilayers and substrates manifests itself as a high density of threading dislocations and large residual strain, which have proven to be detrimental to the performance of high power electronic devices by causing a high leakage current and soft breakdown. The performance of III-nitride power devices may also be limited by immature device processing, particularly the lack of effective edge-termination techniques. It is difficult to perform doping and isolation in selective regions using conventional approaches such as ion implantation and diffusion.

It would therefore be desirable to provide new structures and methods related to fabrication of power electronic devices based on high-quality GaN or AlGaN-based alloys and heterostructures.

### BRIEF DESCRIPTION

In accordance with an embodiment of the invention, a semiconductor device is provided. The semiconductor device includes a substrate comprising one of GaN, AIN and AlₓGa₁₋ₓN. An n⁺ type epitaxial layer is disposed above the substrate and comprises at least one of AlₓGa₁₋ₓN, AlₓIn_{y}Ga_{1-x-y}N and a GaN/AlGaN graded layer. An n⁻ type epitaxial layer is disposed on the n⁺ type epitaxial layer and comprises AlₓGa₁₋ₓN or AlInGaN. A buffer layer is disposed between the substrate and the n⁺ type epitaxial layer. As discussed below, a lightly doped n-type layer is often denoted as “n⁻ type.” Similarly, n⁺ type refers to a heavily doped layer, as discussed below.

In another embodiment of the invention, a semiconductor device is provided. The semiconductor device includes a substrate comprising a material selected from the group consisting of AlN, SiC, GaN, sapphire and combinations thereof. The semiconductor device further includes an anode metal contact, a cathode metal contact and an n type graded layer comprising AlₓGa₁₋ₓN and Al_{y}Ga_{1-y}N, where x<y. The n type graded layer transitions from AlₓGa₁₋ₓN to Al_{y}Ga_{1-y}N in a vicinity of the anode metal contact. An n⁻ type AlₓGa₁₋ₓN epitaxial layer is disposed between the substrate and the n type graded layer.

In yet another embodiment of the invention, a semiconductor device is provided. The semiconductor device includes a substrate comprising a material selected from the group consisting of AlN, SiC, GaN, sapphire and combinations thereof. The semiconductor device further includes a p⁺ type graded layer comprising AlₓGa₁₋ₓN and Al_{y}Ga_{1-y}N (0≦x≦1, 0≦y<1, and y<x). The p⁺ type graded layer transitions from AlₓGa₁₋ₓN to Al_{y}Ga_{1-y}N. An n⁻ AlₓGa₁₋ₓN drift layer is disposed between the substrate and the p⁺ type graded layer.

In accordance with another embodiment of the invention, a semiconductor device is provided. The semiconductor device includes a substrate comprising a material selected from the group consisting of AlN, SiC, GaN, sapphire and combinations thereof. An n⁻ type AlInGaN epitaxial layer is disposed above the substrate. An n⁻ type GaN epitaxial layer is disposed between the substrate and the n⁻ type AlInGaN epitaxial layer.

In accordance with another embodiment of the invention, a semiconductor device is provided. The semiconductor device includes a substrate comprising a material selected from the group consisting of AlN, SiC, GaN, sapphire and combinations thereof. An n⁺ type epitaxial layer is disposed above the substrate and comprises GaN or AlGaN. An n⁻ type epitaxial layer is disposed above the substrate and comprises GaN or AlGaN. A p⁺-n junction grid comprises p⁺ GaN or p⁺ AlGaN and is formed on selective areas of the n⁻ type epitaxial layer. A metal layer is disposed over the p⁺-n junction grid and forms a Schottky contact. Another metal layer is deposited on one of the substrate and the n⁺ type epitaxial layer and forms a cathode electrode.

In accordance with yet another embodiment of the invention, a method of fabricating a semiconductor device, such as a merged PiN/Schottky (MPS) rectifier, is presented. The method includes selectively etching an epitaxial p⁺ GaN layer to form a p⁺-n junction grid on a drift layer comprising n⁻ GaN or AlGaN.

Another method of fabricating a semiconductor device, such as a MPS rectifier, is presented in accordance with an embodiment of the invention. The method includes the steps of forming a mask over a drift layer comprising GaN or AlGaN, and growing p⁺ GaN using an epitaxial regrowth process to form a p⁺-n junction grid.

### DRAWINGS

These and other features, aspects, and advantages of the present invention will become better understood when the following detailed description is read with reference to the accompanying drawings in which like characters represent like parts throughout the drawings, wherein:

FIG. 1 depicts an exemplary Schottky rectifier embodiment of the present invention;

FIG. 2 depicts an exemplary PIN rectifier embodiment of the present invention;

FIG. 3 depicts an exemplary heterostucture Schottky rectifier embodiment of the present invention;

FIG. 4 depicts an exemplary heterostucture PIN rectifier embodiment of the present invention;

FIG. 5 depicts another exemplary heterostucture PIN rectifier embodiment of the present invention;

FIG. 6 depicts an exemplary merged PIN/Schottky (MPS) rectifier embodiment of the present invention;

FIG. 7 illustrates an exemplary configuration of a p+ GaN grid in top view;

FIG. 8 depicts another exemplary MPS rectifier embodiment of the present invention;

FIG. 9 illustrates another exemplary configuration of a p+ GaN grid;

FIG. 10 is a schematic representation of a method of fabricating a MPS rectifier employing an etch-back technique;

FIG. 11 is a schematic representation of another method for fabricating a MPS rectifier that employs a regrowth technique;

FIG. 12 illustrates another method for fabricating a MPS rectifier that employs another regrowth technique; and

FIG. 13 depicts an exemplary Schottky rectifier embodiment of the present invention having an insulating substrate.

### DETAILED DESCRIPTION

It will be understood by those skilled in the art that “n-type” and “p-type” refer to the majority of charge carriers, which are present in a respective layer. For example, in n-type layers, the majority carriers are electrons, and in p-type layers, the majority carriers are holes (the absence of electrons). As used herein, n⁺ and n⁻ refer to high (greater than 1×10¹⁷ cm⁻³) and low (greater than 5×10¹⁶ cm⁻³) doping concentrations of the dopants, respectively.

As used herein, the term “about” should be understood to indicate plus or minus ten percent (+/−10%).

Embodiments of the present invention are described below in detail with reference to the accompanying drawings. The same reference numerals denote the same parts throughout the drawings.

The disclosure presents a number of devices based on Gallium nitride (GaN), aluminum gallium nitride (AlₓGa₁₋ₓN) and aluminum indium gallium nitride (AlₓIn_{y}Ga_{1-x-y}N). Here, the x and y refers to the atomic fraction of the respective element in the composition, where x varies from about 0 to about 1 (0≦x≦1), y varies from about 0 to about 1 (0≦y≦1), and x+y varies from about 0 to about 1 (0≦x+y≦1). It is to be understood that the x and y of the composition may vary from one embodiment to the other.

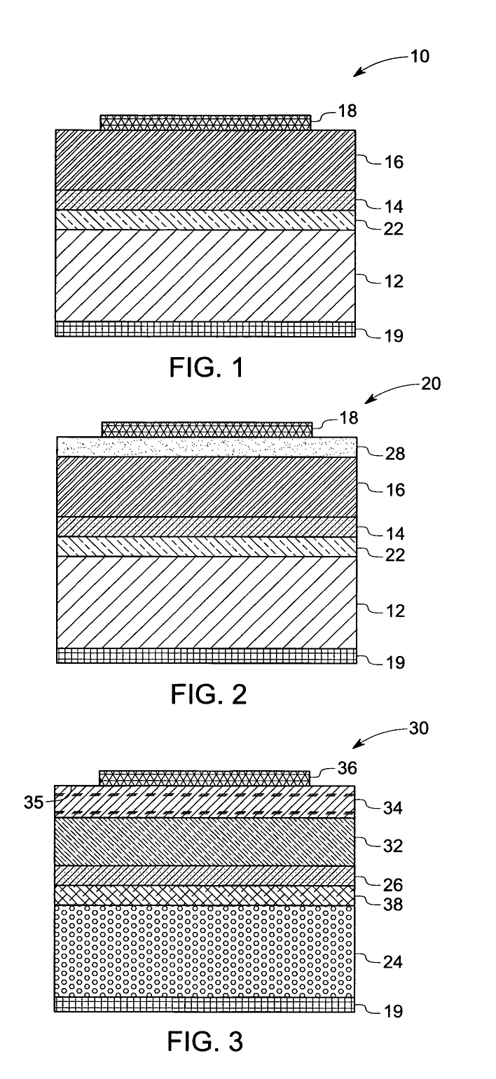

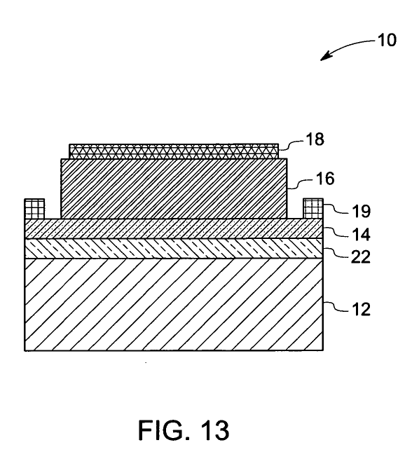

FIGS. 1 and 13 depict example Schottky rectifier 10 embodiments of the invention. The substrate 12 is formed of GaN, AlGaN or AlN. In particular embodiments, the substrate 12 is a perfect or nearly-perfect chemical, crystallographic, lattice-constant, and thermal-expansion match to the AlGaN device structure. The epitaxial growth of the device on such substrates is referred to herein as “homoepitaxy.” Homoepitaxy enables the growth of high quality device structures with reduced defects and strain and simplifies the procedures for growth, fabrication, and packaging. In one embodiment, the dislocation density of the substrate and the overlying epilayer is less than about 10⁷ cm⁻² and in another embodiment the dislocation density is less than about 10⁵ cm⁻². The dislocation density is a measure of the dislocations that are present in a quantity of a material. An n⁺ type layer 14 is epitaxially grown over the substrate 12. The n⁺ layer is included for an insulating AlN substrate and is optionally included on a conducting GaN substrate. The epitaxial growth may be performed using techniques commonly known to one skilled in the art, for example metal-organic chemical vapor deposition (MOCVD) may be employed to grow the n⁺ layer. For the exemplary embodiment depicted in FIG. 1, the n⁺ layer is formed of AlₓGa₁₋ₓN, AlₓIn_{y}Ga_{1-x-y}N or a GaN/AlGaN graded layer. The n⁺ doping is achieved by adding n type dopants used for III-V group semiconductors, non-limiting examples of which include silicon, oxygen and sulfur. According to a particular embodiment, the concentration of the doping is in a range of about 1×10¹⁷ cm⁻³ to about 1×10²⁰ cm⁻³. In one example, the thickness of the n⁺ layer is between about 0-5μm, although other thicknesses may be used.

For the structure indicated in FIG. 1, an n⁻ type drift layer 16 formed of AlGaN or AlInGaN is epitaxially grown over the n⁺ type layer 14. The lower doping in n⁻ type may be achieved, for example, by using an unintentionally-doped layer or a low silicon (Si) doping. The light Si doping improves the electron mobility in the nitride layer and in turn improves the conductivity of the layer. In one embodiment, the silicon doping is less than about 5×10¹⁶ cm⁻³. The n type may be grown by standard techniques, non-limiting examples of which include metal-organic chemical vapor deposition (MOCVD) and molecular beam epitaxy (MBE), and the dopants may be added during the growth process. To precisely control the doping concentration in the drift layer at low levels, it is important to reduce unintentional doping and compensation caused by common impurities such as C, H and O. In one embodiment, the concentration of the impurities in the drift layer is less than about 1×10¹⁷ cm⁻³ and in another embodiment it is less than about 1×10^{l5} cm⁻³. In one example, the n⁻ type drift layer thickness is between about 1 μm and about 100 μm.

Additionally, for the structure indicated in FIG. 1, if the epilayer and substrate 12 have different compositions, a buffer layer 22 is optionally included to help accommodate the small mismatch of lattice constant and thermal expansion coefficient. The buffer layer also acts as a stress relief and enables a thick layer growth without film cracking. For certain embodiments, the buffer layer 22 comprises an AlₓGaN/Al_{y}GaN superlattice or a delta-doped layer. For example, AlGaN may be grown on a GaN substrate using a buffer layer formed of an GaN/AlGaN superlattice. A superlattice may be formed, for example, by thin crystal layers, where the properties of these layers, such as thickness and composition, repeat periodically. For certain examples, the superlattice thickness is in a range of about 100 nanometers to about few micrometers.

For the exemplary embodiment depicted in FIG. 1, a Schottky contact 18 is formed over the n⁻ layer 16, and an ohmic contact 19 is formed on the backside of the substrate 12 to form a Schottky rectifier. The deposition of the metal may be performed, for example, using e-beam evaporation or sputtering techniques, which are known in the art. The Schottky metal may be selected from a group of high work function metals including, but not limited to, platinum (Pt), nickel (Ni), gold (Au), and any alloys thereof. The ohmic metal may be selected from a group of low work function metals including, but not limited to, Ti, Al, and any alloys thereof. For insulating substrates 12, the ohmic contact 19 is formed on the n⁺ layer 14, as shown for example in FIG. 13. For the exemplary embodiment depicted in FIG. 13, the rectifier has a lateral configuration with a mesa structure, which may be defined using photolithography and plasma etching. Conventional field-plate edge termination, or epitaxially grown p⁺ GaN guard rings as described below may be employed to protect the rectifier from surface breakdown.

For particular embodiments, the dislocation density of the substrate and the overlying epilayer is less than about 10⁷ cm⁻², and in certain embodiments the dislocation density is less than about 10⁵ cm⁻². Likewise, in accordance with particular embodiments, the impurity content of the n⁺ and n⁻ layers is less than about 10¹⁷ cm⁻³, and in certain embodiments it is less than about 10¹⁵ cm⁻³.

In certain embodiments, the substrate 12 comprises GaN, and the buffer layer 22 and the n⁺ layer 14 comprise an AlGaN/GaN superlattice and AlGaN, respectively. In another embodiment, the substrate 12 comprises GaN, and the n⁺ layer 14 comprises AlInGaN. In yet another embodiment, the substrate comprises GaN, and the n⁺ layer 14 comprises a graded layer transitioning from GaN in a vicinity of the substrate to AlGaN in a vicinity of the n− type layer. In accordance with another embodiment, the substrate 12 comprises AlN, the n⁺ epilayer 14 comprises AlGaN and the buffer layer 22 comprises an AlN/AlGaN superlattice.

Another embodiment of the present invention directed to a PIN rectifier is shown in FIG. 2. For the exemplary embodiment depicted in FIG. 2, the substrate 12 comprises GaN, AlGaN or AlN. An n⁺ type layer 14 is then epitaxially grown over the substrate 12. As discussed above, the epitaxial growth may be performed using known techniques, such as MOCVD and MBE. The n⁺ layer is formed of AlₓGa₁₋ₓN, AlₓIn_{y}Ga_{1-x-y}N or a GaN/AlGaN graded layer. Techniques for achieving the n⁺ doping are discussed above. An n⁻ type layer 16 comprising AlGaN or AlInGaN is epitaxially grown over the n⁺ type layer. The lower doping in n⁻ type and example growth techniques are discussed above. Optionally, a buffer layer 22 is employed to take into account the lattice mismatch between the substrate 12 and the n⁺ layer 14. For the exemplary embodiment depicted in FIG. 2, a p⁺ type AlGaN or AlInGaN layer 28 is epitaxially grown over the n⁻ layer 16 to form a PIN rectifier 20. In a non-limiting example, the p+ layer is epitaxially grown over the n⁻ layer 16 through MOCVD in the presence of dopants, such as magnesium or zinc. The PIN rectifier 20 further includes a p-type ohmic contact 18, which is deposited on the p⁺ layer, and an n− type ohmic contact 19, which is formed on either the backside of the substrate 12 or on the n⁺ layer 14 (as shown for example in FIG. 13). Exemplary p-type contacts 18 are formed of Au, Pt, Ni, and alloys thereof. Exemplary n-type contacts 19 are formed of Ti, Al and alloys thereof.

In accordance with another embodiment, a Schottky rectifier 30 is presented in FIG. 3. The substrate 24 is formed of one or more of AlN, SiC, GaN, and sapphire. An n⁺ layer 26 is epitaxially grown on the substrate. The n⁺ layer is formed of GaN or AlGaN. FIG. 3 illustrates an example device grown on a substrate other than GaN. For the illustrated embodiment, a buffer layer 38 is disposed between the substrate 24 and the n⁺ layer 26, to address the lattice mismatch between them. For particular examples, the buffer layer 38 is formed of a low-temperature AlGaN or GaN layer on sapphire, and is formed of an AlN or AlGaN layer on SiC. An n⁻ type GaN drift layer 32 is grown over the n⁺ layer. For a particular embodiment, the n⁻ layer has a low doping concentration of less than about 5×10¹⁶ cm⁻³. An n− type graded layer 34 is epigrown on the n⁻ layer 32. In one example, the graded layer 34 is formed of n⁻ type GaN and AlGaN and is graded from GaN in the vicinity of the n⁻ layer 32 to AlGaN toward the surface 35. The incorporation of graded layer 34 provides several benefits. Since AlGaN has a larger bandgap than GaN, it can tolerate a higher electric field. The graded layer may eliminate the 2-dimensional electron gas (2 DEG), which may exist at an abrupt AlGaN/GaN interface, and thus reduces reverse leakage in the rectifier. In another embodiment, the graded layer is replaced with an n⁻ AlInGaN layer, which is lattice matched to GaN but has a wider bandgap. A metal contact 36 is formed over the surface 35. In yet another embodiment, the drift layer comprises an n⁻ type AlₓGa₁₋ₓN (0≦x<1) layer and an n− graded layer from AlₓGa₁₋ₓN (0≦x<1) to Al_{y}Ga_{1-y}N (0<y≦1, y>x). The Schottky metal 36 formed on the surface 35 may be selected from a group of high work function metal including but not limited to Pt, Ni, Au, and alloys thereof. If the substrate is insulating, such as sapphire and AlN, a mesa is formed by etching down to the n⁺ layer on which the cathode metal is deposited (FIG. 13). If the substrate is conductive for example, SiC or GaN, then the cathode may be added on the back of the substrate (as indicated in FIG. 3, for example), and the heavily doped n⁺ layer 34 may be replaced. Conventional field plate edge termination, or epitaxially grown p⁺ GaN guard rings as described below may be employed to protect the rectifier from surface breakdown.

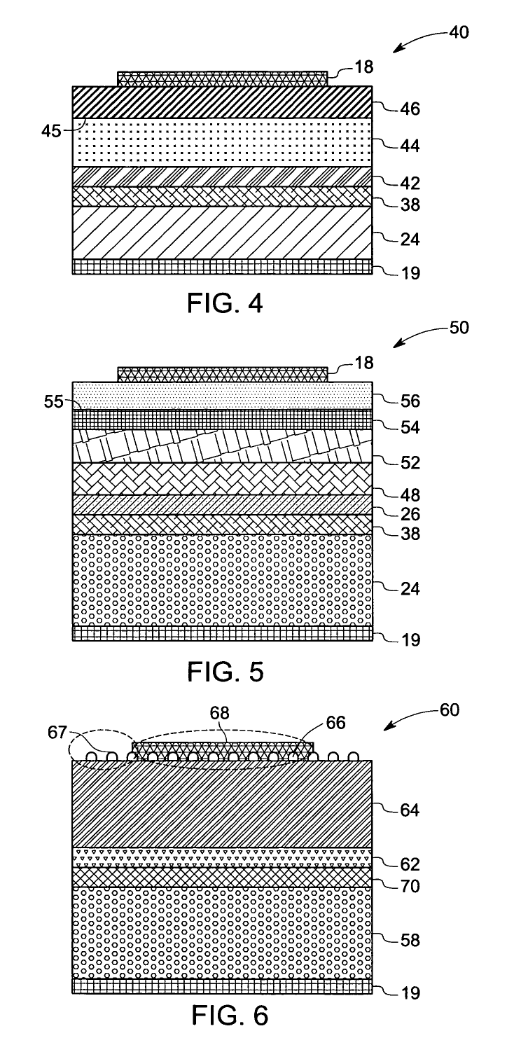

FIG. 4 presents a PIN rectifier 40 in accordance with another embodiment of the present invention. The substrate 24 is formed of AlN, SiC, GaN or sapphire. An optional n⁺ layer 42 formed of AlGaN is disposed over the substrate. Additionally, a buffer layer 38 may be provided between the substrate 24 and n⁺ layer 42 to address the lattice mismatch between the two. An AlGaN drift layer 44 is epitaxially grown on the n⁺ layer 42. Beneficially, the drift layer ensures a high voltage blocking capability. A p⁺ graded layer 46 formed of AlGaN/GaN is provided, where the graded layer transitions from AlGaN to GaN in the vicinity of the surface 45. The top p⁺ GaN layer would facilitate the formation of high quality p-type ohmic metallization. In another embodiment, the AlGaN drift layer and graded layer are replaced with AlInGaN layers, which are lattice matched to GaN but have a wider bandgap. In yet another embodiment, the drift layer comprises n⁻ type AlₓGa₁₋ₓN (0<x≦1), and the p⁺ layer comprises p⁺ AlₓGa₁₋ₓN (0≦x≦1) graded to p⁺ Al_{y}Ga_{1-y}N (0≦y<1, y<x). The p-type metal contact is added on the p⁺ layer and comprises, for example, one or more of Pt, Ni, Au and their alloys, and the n-type contact is formed on the n⁺ layer, and comprises, for example, Al, Ti and their alloys. Additionally, if the substrate is conductive, then the metal contact 19 may be added on the backside of the substrate instead of being added on the n⁺ layer. Dielectric passivation may be employed to reduce surface leakage and protect the PiN rectifier from surface breakdown.

A heterostructure PIN rectifier 50 in accordance with an embodiment of the invention is shown in FIG. 5. The substrate 24 is formed of AlN; SiC, sapphire or GaN. An n⁺ GaN epitaxial layer 26 is disposed on the substrate. An n− layer 48 formed of GaN is then grown on the n⁺ layer. An n⁻ layer of AlInGaN 52, which is lattice matched to the n+ layer, is disposed on the n⁻ layer 48. Further, a p⁺ layer 54 formed of AlInGaN is disposed on the n− layer 52. The highest electric field in the PIN rectifier is at the p-n junction interface, where breakdown usually occurs. The voltage blocking capability of the PIN rectifier can be markedly increased by utilizing a wider bandgap AlInGaN. A p⁺ layer 56 formed of GaN is epitaxially grown on p⁺ layer 54, to improve the quality of p doping and the quality of the p-type ohmic contact. Optionally, a buffer layer 38 is included between the substrate 24 and n⁺ layer 26 to accommodate the lattice mismatch between the two. The buffer acts as a stress relief layer and the quality of the overlying epilayers on the substrate is enhanced.

FIG. 6 presents a merged PIN/Schottky (MPS) rectifier 60 in accordance with another embodiment of the invention. The substrate 58 is formed of AlN, SiC, GaN or sapphire. An optional n⁺ layer 62 formed one of GaN or AlGaN is disposed on the substrate. Further, an n⁻ drift layer 64 formed of GaN or AlGaN is disposed on the n⁺ layer. P⁺ GaN or AlGaN is selectively regrown atop the n⁻ drift layer 64 to form a p⁺-n junction grid (66, 67) comprising an outer grid (67) and an inner grid (66). The outer p⁺ grid 67, which is located at the edge of and outside the Schottky metal 68 and includes at least one p⁺ GaN region, is formed of so-called guard ring(s), and is employed to reduce the sharp-edge effect and prevent surface breakdown of the rectifier. Similar guard rings can also be applied to all Schottky rectifiers described earlier. For certain embodiments, the outer p⁺ grid 67 comprises 1-3 rings including the ring at the Schottky edge. The p⁺-n junctions 66 under the Schottky metal 68 are designed so that their depletion regions intersect under the Schottky barrier when the reverse bias exceeds a certain voltage. This potential barrier shields the Schottky barrier from the applied voltage, preventing Schottky barrier lowering and large leakage current. The breakdown voltage can thus be significantly increased. At forward bias, the p⁺-n junctions 66 produce the injection of holes into the n− drift region, resulting in conductivity modulation. The MPS rectifier thus works in a manner similar to a PiN rectifier and has a lower on-resistance than regular Schottky rectifiers.

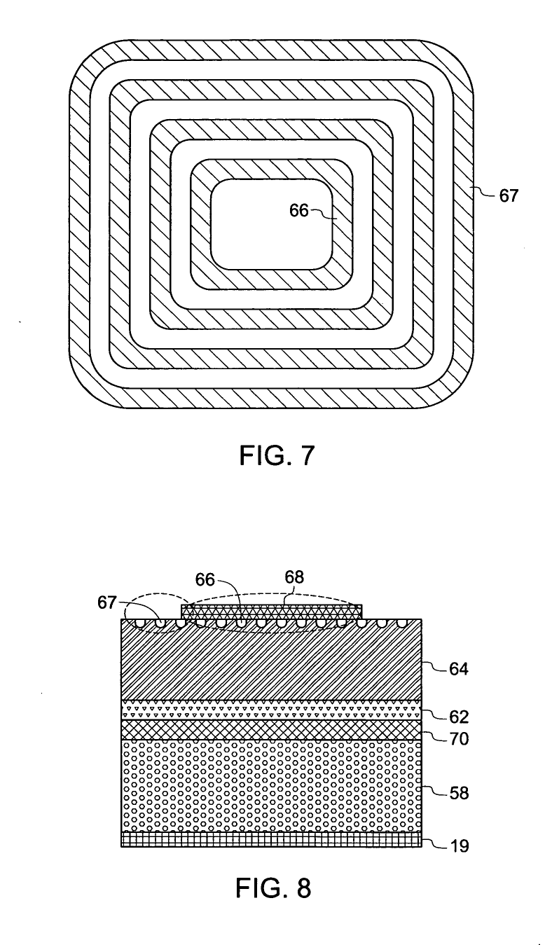

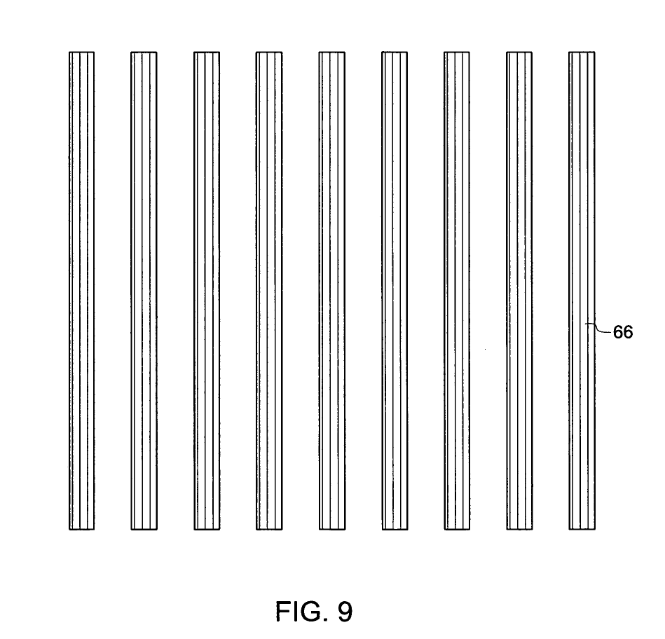

It is difficult to form p⁺ type doping regions in GaN using ion implantation, due to the low activation percentage of the dopant. In addition, ion implantation could create large ion induced damage, which may cause compensation or even type conversion. Accordingly, the present invention forms the p⁺ GaN regions by employing an etch-back or re-growth technique, as discussed below. In one embodiment as shown in FIG. 6, the p⁺ regions 66, 67 are formed atop the n− drift layer in selective areas. FIG. 7 illustrates an exemplary configuration of the p⁺-GaN grid, which corresponds to the shaded region. In another embodiment depicted in FIG. 9, the regrown p⁺ GaN grid takes the form of an array of straight lines. The typical width of the p⁺ regions is in the range of about 0.5-50 μm, and typical spacing is about 0.5-50 μm. The MPS rectifier also includes an anode metal, which is formed on the p⁺ GaN grid, and a cathode metal 19, which is deposited on the n⁺ layer or the backside of the substrate.

A MPS rectifier 60 according to another embodiment of the invention is presented in FIG. 8. The substrate 58 is formed of AlN, SiC, GaN or sapphire. An optional n⁺ layer 62, which is formed of GaN or AlGaN, is disposed on the substrate. Further, an n-drift drift layer 64 formed of GaN or AlGaN is disposed on the n⁺ layer. P⁺ GaN is deposited in selective areas by employing a regrowth technique to form an integrated p⁺-n junction grid 66, 67. For the exemplary embodiment depicted in FIG. 8, the p⁺-n junction grid 66, 67 extends into the n⁻ layer 64, in contrast with the embodiment illustrated in FIG. 6. Example forms for the p⁺-n junction grid are shown in FIG. 7 or 9. The Schottky contact 68 is added on the p⁺ region and the underlying n⁻ layer. The cathode metal 19 is deposited on the n⁺ layer or on the backside of the substrate.

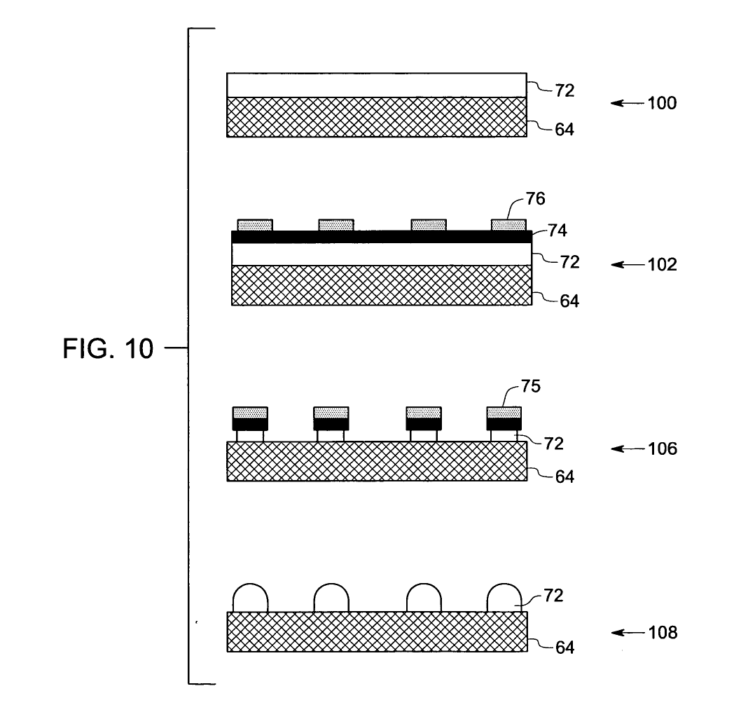

In accordance with another embodiment of the invention, a method of fabricating a device is shown in FIG. 10. The method comprises forming a p⁺ GaN grid 72 on a drift layer 64 comprising GaN or AlGaN. In step 100, a p⁺ GaN layer 72 is epitaxially grown on the drift layer 64. Step 102 involves patterning the p⁺ GaN layer 72, using lithography, for example. For the illustrated example, the patterning includes application of an etching mask 75, which comprises, for example, a photoresist layer 76, a dielectric layer 74, a metal layer (not shown), or combinations thereof. For the illustrated example, the mask 75 comprises a photoresist layer 76 and a dielectric layer 74. In other embodiments, the mask comprises a photoresist layer. Exemplary dielectrics include, but are not limited to, silicon dioxide, silicon nitride and aluminum nitride. Exemplary metals include, but are not limited to, Ni, Au and Ti. In the step 106, the portion of the p⁺ layer 72 without the envelope of the etching mask 75 is etched to form a p⁺ GaN grid 72. A plasma process, such as reactive ion etching (RIE) and inductively coupled plasma (ICP) etching, is effective for GaN etching. However, plasma is known to cause substantial damage in the etched GaN. A low-energy plasma etching is desirable, and wet etching would be ideal. The etch mask 75 is then removed in step 108. According to a particular embodiment, the concentration of p doping in the p⁺ GaN layer 72 is between about 1×10¹⁷ cm⁻³ to about 1×10²⁰ cm⁻³.

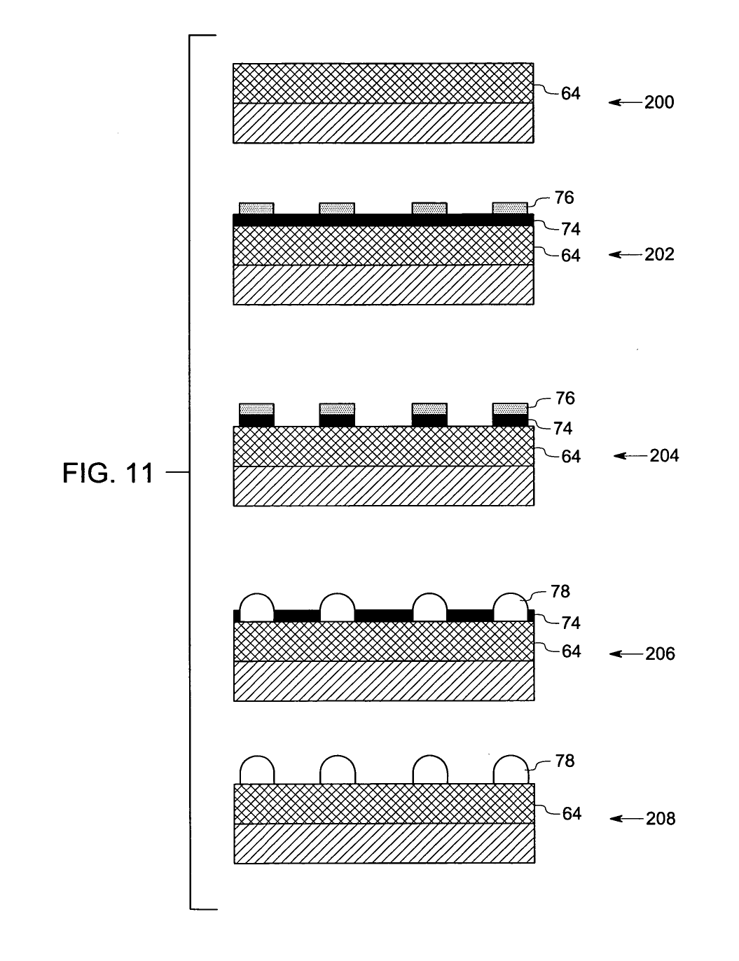

FIG. 11 depicts another method employing a re-growth technique, in accordance with another embodiment of the invention. A drift layer 64 formed of GaN or AlGaN is provided in step 200. In step 202, a dielectric layer 74 is disposed on the drift layer 64. Example dielectrics include, but are not limited to, silicon dioxide, silicon nitride and aluminum nitride. A resist layer 76 is applied over the dielectric layer. In a non-limiting example a photoresist layer is applied over the dielectric layer. A mask (not shown) may be employed for patterning. The exposed dielectric layer is then etched in step 204, using, for example, wet etching, reactive ion beam etching or reactive ion etching to expose the n− layer for p⁺ re-growth. p⁺ GaN 78 is then deposited on n− layer in step 206 in a manner similar to the MOCVD lateral epitaxial overgrowth (LEO) technique which comprises partially masking a substrate and subsequently regrowing over the masked substrate. The dielectric layer remaining is then etched in step 208 to form a p⁺ GaN grid 78.

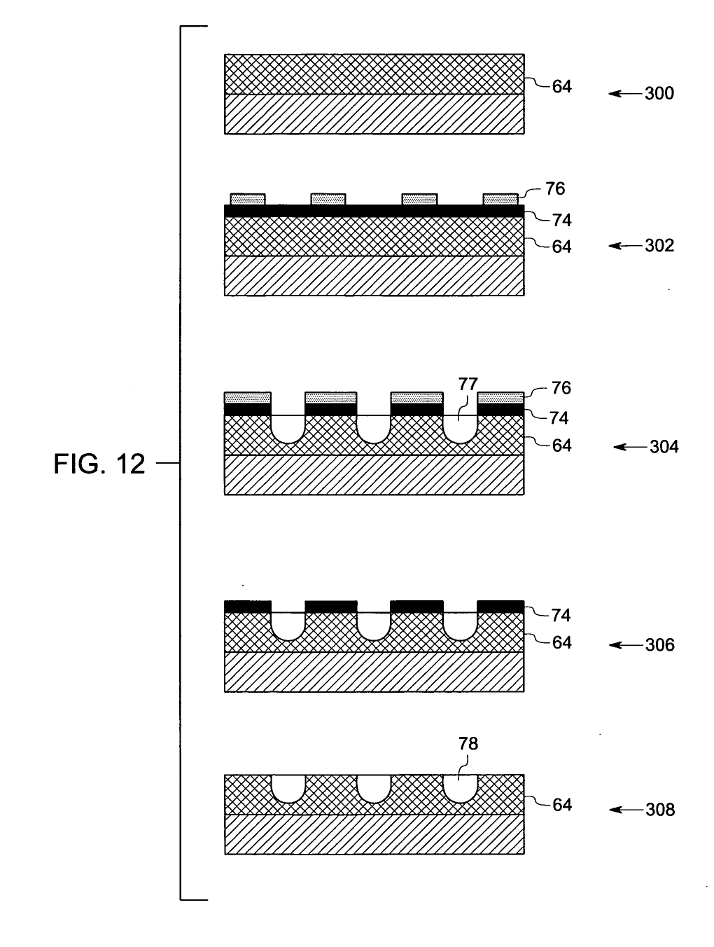

In yet another embodiment, a method of forming a p⁺ GaN grid using a regrowth technique is shown in FIG. 12. A drift layer 64 comprising GaN or AlGaN is provided in step 300. In step 302, a dielectric layer 74 is disposed on the drift layer 64. Example dielectric materials include, but are not limited to, silicon dioxide, silicon nitride and aluminum nitride. A resist layer 76 is applied over the dielectric layer. In a non-limiting example, the resist layer consists of a photoresist layer and is applied over the dielectric layer. A mask (not shown) may be employed for patterning. The exposed dielectric layer is etched, and the exposed n⁻ GaN layer 64 is then partially etched in step 304 to form trenches 77. The etching may be carried out through techniques known to one skilled in the art, such as wet etching, dry etching and electron beam etching. p⁺ GaN 78 is then grown to fill up the trenches 77 in step 306 to form a p⁺ GaN grid 78 extending into the drift layer 64.

The p⁺ GaN grid (guard rings) produced using the techniques described above can be applied to any other types of GaN or AlGaN-based power devices as the edge termination. The p⁺ GaN grid can be integrated into any other types of the Schottky rectifiers to form corresponding MPS rectifiers.

Although only certain features of the invention have been illustrated and described herein, many modifications and changes will occur to those skilled in the art. It is, therefore, to be understood that the appended claims are intended to cover all such modifications and changes as fall within the true spirit of the invention.

1. A semiconductor device comprising:
a substrate comprising one of GaN, AlN and AlₓGa₁₋ₓN;
an n⁺ type epitaxial layer disposed above said substrate and comprising at least one of AlₓGa₁₋ₓN, AlₓIn_{y}Ga_{1-x-y}N and a GaN/AlGaN graded layer;
an n⁻ type epitaxial layer disposed on said n⁺ type epitaxial layer and comprising AlₓGa₁₋ₓN or AlInGaN; and
a buffer layer disposed between said substrate and said n⁺ type epitaxial layer.

2. The semiconductor device of claim 1, further comprising an anode metal layer disposed on said n− type epitaxial layer, and a cathode metal layer deposited on one of said substrate and said n⁺ layer, wherein said semiconductor device comprises a Schottky rectifier.

3. The semiconductor device of claim 1, further comprising:
a p⁺ type AlₓGa₁₋ₓN layer disposed on said n− type epitaxial layer;
an anode metal layer disposed on said p⁺ AlₓGa₁₋ₓN layer; and
a cathode metal layer deposited on one of said substrate and said n⁺ layer, wherein said semiconductor device comprises a PIN rectifier.

4. The semiconductor device of claim 3,
wherein said substrate comprises GaN, and
wherein said n⁺, n⁻ and p⁺ type epitaxial layers comprise AlₓGa₁₋ₓN.

5. The semiconductor device of claim 3,
wherein said substrate comprises GaN, and
wherein said n⁺, n⁻ and p⁺ type epitaxial layers comprise AlₓIn_{y}Ga_{1-x-y}N which is lattice matched to the substrate.

6. The semiconductor device of claim 3, wherein said substrate comprises GaN, wherein said n⁻ type epitaxial layer comprises a graded layer transitioning from GaN in a vicinity of said n⁺ type epitaxial layer to AlGaN in a vicinity of said p⁺ type epitaxial layer, and wherein said p⁺ type epitaxial layer comprises a graded layer transitioning from AlGaN in a vicinity of said n⁻ layer to GaN in a vicinity of said anode metal layer.

7. The semiconductor device of claim 3,
wherein said substrate comprises AlN, and
wherein said n⁺, n⁻ and p⁺ type epitaxial layers comprise AlₓGa₁₋ₓN.

8. The semiconductor device of claim 1, wherein said n⁻ type epitaxial layer has a Silicon doping of less than about 5×10¹⁶/cm³.

9. The semiconductor device of claim 1, wherein said n⁻ type epitaxial layer has an impurity concentration of less than about 1×10¹⁷/cm³.

10. The semiconductor device of claim 1, wherein said n⁻ type epitaxial layer has an impurity concentration of less than about 1×10¹⁵/cm³.

11. The semiconductor device of claim 1, wherein said buffer layer comprises an AlₘGa₁₋ₘN/AlₙGa₁₋ₙN superlattice.

12. A semiconductor device comprising:
a substrate comprising a material selected from the group consisting of AlN, SiC, GaN, sapphire and combinations thereof;
an anode metal contact;
a cathode metal contact;
an n-type graded layer comprising AlₓGa₁₋ₓN and Al_{y}Ga_{1-y}N and transitioning from AlₓGa₁₋ₓN to Al_{y}Ga_{1-y}N in a vicinity of said anode metal contact, wherein x<y; and
an n⁻ type AlₓGa₁₋ₓN epitaxial layer disposed between said substrate and said n-type graded layer.

13. The semiconductor device of claim 12, further comprising:
an n⁺ type GaN epitaxial layer disposed between said substrate and said n⁻ type GaN epitaxial layer.

14. The semiconductor device of claim 12, further comprising:
a buffer layer disposed between said substrate and said n⁺ type GaN epitaxial layer.

15. A semiconductor device comprising:
a substrate comprising a material selected from the group consisting of AlN, SiC, GaN, sapphire and combinations thereof;
a p⁺ type graded layer comprising AlₓGa₁₋ₓN and Al_{y}Ga_{1-y}N and transitioning from AₓGa₁₋ₓN to Al_{y}Ga_{1-y}N, wherein 0≦x≦1, wherein 0≦y<1, and wherein y<x; and
an n⁻ AlGaN drift layer disposed between said substrate and said p⁺ type graded layer.

16. The semiconductor device of claim 15, further comprising an n⁺ type AlGaN epitaxial layer disposed between said substrate and said n⁻ AlGaN drift layer.

17. The semiconductor device of claim 15, further comprising a buffer layer disposed between said substrate and said n⁻ AlGaN drift layer.

18. A semiconductor device comprising:
a substrate comprising a material selected from the group consisting of AlN, SiC, GaN, sapphire and combinations thereof;
an n⁻ type AlInGaN epitaxial layer disposed above said substrate; and
an n⁻ type GaN epitaxial layer disposed between said substrate and said n⁻ type AlInGaN epitaxial layer.

19. The semiconductor device of claim 18, further comprising:
a p⁺ type GaN epitaxial layer; and
a p⁺ type AlInGaN epitaxial layer disposed between said substrate and said p⁺ type GaN epitaxial layer, wherein said p⁺ type AlInGaN epitaxial layer is lattice matched to said p⁺ type GaN epitaxial layer.

20. The semiconductor device of claim 18, further comprising:
an n⁺ type GaN epitaxial layer disposed between said substrate and said n⁻ type GaN epitaxial layer.

21. The semiconductor device of claim 18, further comprising a buffer layer disposed between said substrate and said n⁻ type GaN epitaxial layer.

22. A semiconductor device comprising:
a substrate comprising a material selected from the group consisting of AlN, SiC, GaN, sapphire and combinations thereof;
an n⁻ type epitaxial layer disposed above said substrate and comprising GaN or AlGaN;
a p⁺-n junction grid comprising p⁺ GaN or p⁺ AlGaN formed on selective areas of said n− type epitaxial layer;
a metal layer disposed over said p+-n junction grid and forming a Schottky contact; and
a metal layer deposited on one of said substrate and said n⁺ type epitaxial layer and forming a cathode electrode.

23. The semiconductor device of claim 22, further comprising an n⁺ type epitaxial layer disposed between said substrate and said n⁻ type epitaxial layer, wherein said n⁺ type epitaxial layer comprises GaN or AlGaN.

24. The semiconductor device of claim 23, further comprising a buffer layer disposed between said substrate and said n⁺ type epitaxial layer.

25. The semiconductor device of claim 22, wherein said p⁺-n junction grid comprises at least one epitaxially grown p⁺ GaN guard ring positioned at an edge of and outside the Schottky contact.

26. The semiconductor device of claim 22, wherein said p⁺-n junction grid is annular or rectangular in shape or comprises an array of straight lines.

27. The semiconductor device of claim 22, wherein said p⁺-n junction grid extends into said n⁻ type epitaxial layer.

28. The semiconductor device of claim 22, wherein the p⁺-n junction grid is disposed on said n⁻ type epitaxial layer.

29. The semiconductor device of claim 22, wherein said p⁺-n junction grid is characterized by a width in a range of about 0.5-50 μm and a spacing in a range of about 0.5-50 μm.

30. A method of fabricating a semiconductor device, said method comprising forming a p⁺-n junction grid on a drift layer comprising GaN or AlGaN.

31. The method of claim 30, wherein said forming step comprises:
epitaxially growing a p⁺ GaN layer on the drift layer;
patterning the p⁺ GaN layer using lithography; and
etching the p⁺ GaN in a plurality of selective areas to forming the p⁺-n junction grid.

32. A method of fabricating a semiconductor device comprising:
forming a mask over a drift layer comprising GaN or AlGaN; and
growing p⁺ GaN using an epitaxial regrowth process to form a p⁺-n junction grid.

33. The method of claim 32, wherein the mask comprises a dielectric material selected from the group consisting of silicon dioxide, silicon nitride, aluminum nitride and combinations thereof.

34. The method of claim 32, wherein said growing step comprises growing the p⁺ GaN on the drift layer, such that the p⁺-n junction grid is formed on the drift layer.

35. The method of claim 32, wherein said growing step further comprises:
etching the drift layer using the mask to form a plurality of trenches; and
growing the p⁺ GaN within the trenches, such that the p⁺-n junction grid extends into the drift layer.
